(19) United States
(12) Patent Application Publication
(10) Pub. No.: US 2021/0132804 A1
(43) Pub. Date: May 6, 2021

(54) STORAGE DEVICE AND METHOD OF OPERATING THE STORAGE DEVICE

(71) Applicant: SK hynix Inc., Icheon-si Gyeonggi-do (KR)

(72) Inventor: Jiman HONG, Icheon-si Gyeonggi-do (KR)

(73) Assignee: SK hynix Inc., Icheon-si Gyeonggi-do (KR)

(21) Appl. No.: 16/922,778

(22) Filed: Jul. 7, 2020

(30) Foreign Application Priority Data
Nov. 5, 2019 (KR) 10-2019-0140516

(51) Int. Cl. G06F 3/06; G06F 11/07

(52) U.S. Cl. CPC G06F 3/064; G06F 3/0653; G06F 11/076; G06F 3/0673; G06F 3/0619

(57) ABSTRACT

A memory controller including a search operation manager. The search operation manager counts a number of times an optimum read voltage search operation is performed on the plurality of memory blocks, and determines a target block in which the number of times the optimum read voltage search operation is performed exceeds a reference number of times. The block manager sets the target block as a bad block.

### CROSS-REFERENCE TO RELATED APPLICATION

The present application claims priority under 35 U.S.C. § 119(a) to Korean patent application number 10-2019-0140516, filed on Nov. 5, 2019, in the Korean Intellectual Property Office, the entire disclosure of which is incorporated herein by reference.

### BACKGROUND

### 1. Technical Field

The present disclosure relates to an electronic device, and more particularly, to a storage device and a method of operating the storage device.

### 2. Related Art

A storage device is a device that stores data under control of a host device such as a computer or a smartphone. A storage device may include a memory device in which data is stored and a memory controller controlling the memory device. The categorization of memory devices are divided into volatile memory devices and non-volatile memory devices.

The volatile memory device is a device that stores data only when power is supplied and loses the stored data when the power supply is cut off. The volatile memory device includes a static random access memory (SRAM), a dynamic random access memory (DRAM), and the like.

The non-volatile memory device is a device that does not lose data even though power is cut off. The non-volatile memory device include a read only memory (ROM), a programmable ROM (PROM), an electrically programmable ROM (EPROM), an electrically erasable and programmable ROM (EEPROM), a flash memory, and the like.

### SUMMARY

A memory controller controlling a memory device including a plurality of memory blocks according to an embodiment of the present disclosure may include a search operation manager and a block manager. The search operation manager may be configured to count a number of times an optimum read voltage search operation is performed on the plurality of memory blocks, and determine a target block in which the number of times the optimum read voltage search operation is performed exceeds a reference number of times. The block manager sets the target block as a bad block.

A storage device according to an embodiment of the present disclosure may include a memory device including a plurality of memory blocks, and a memory controller. The memory controller may be configured to count a number of times an optimum read voltage search operation is performed on the plurality of memory blocks, and determining a target block in which the number of times the optimum read voltage search operation is performed exceeds a reference number of times among the plurality of memory blocks, based on a result of the counting.

A method of operating a storage device including a plurality of memory blocks according to an embodiment of the present disclosure may include counting a number of times an optimum read voltage search operation is performed on the plurality of memory blocks.

### BRIEF DESCRIPTION OF THE DRAWINGS

FIG. 1 is a diagram for describing a storage device according to an embodiment of the present disclosure.

FIG. 2 is a diagram for describing a structure of a memory device of FIG.

FIG. 3 is a diagram for describing a memory cell array of FIG. 2.

FIG. 4 is a diagram for describing an optimum read voltage search operation according to an embodiment.

FIG. 5 is a diagram for describing a configuration and an operation of a memory controller of FIG. 1.

FIG. 6 is a diagram for describing a search table storage of FIG. 5 according to an embodiment.

FIG. 7 is a diagram for describing the search table storage of FIG. 5 according to another embodiment.

FIG. 8 is a diagram for describing an operation of the storage device of FIG. 1 according to an embodiment.

FIG. 9 is a diagram for describing determination of a target block according to an embodiment.

FIG. 10 is a diagram for describing the determination of the target block according to other embodiments.

FIG. 11 is a diagram for describing the determination of the target block according to other embodiments.

FIG. 12 is a diagram for describing an embodiment of the memory controller of FIG.

FIG. 13 is a block diagram illustrating a memory card system to which the storage device according to an embodiment of the present disclosure is applied.

FIG. 14 is a block diagram illustrating a solid state drive (SSD) system to which the storage device according to an embodiment of the present disclosure is applied.

FIG. 15 is a block diagram illustrating a user system to which the storage device according to an embodiment of the present disclosure is applied.

### DETAILED DESCRIPTION

Embodiments according to the concept of the present disclosure may be implemented in various forms and should not be construed as being limited to the embodiments described in the specification or application. Hereinafter, an embodiment of the present disclosure will be described with reference to the accompanying drawings.

An embodiment of the present disclosure provides a storage device having improved block management performance, and a method of operating the storage device.

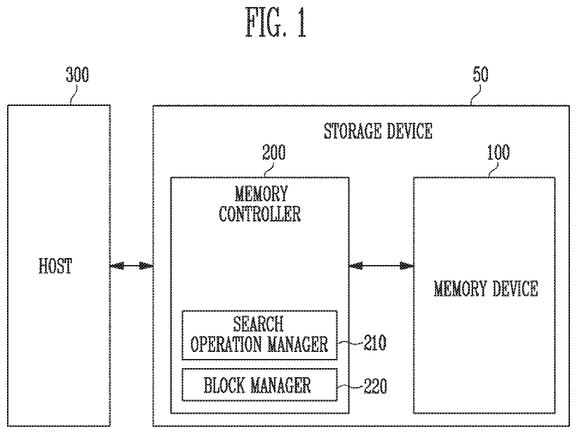

FIG. 1 is a diagram for describing a storage device according to an embodiment of the present disclosure.

Referring to FIG. 1, the storage device 50 may include a memory device 100 and a memory controller 200 that controls an operation of the memory device. The storage device 50 is a device that stores data under control of a host 300 such as a cellular phone, a smartphone, an MP3 player, a laptop computer, a desktop computer, a game player, a TV, a tablet PC, or an in-vehicle infotainment system.

The storage device 50 may be manufactured as one of various types of storage devices according to a host interface that is a communication method with a host 300. For example, the storage device 50 may be configured as any one of various types of storage devices such as an SSD, a multimedia card in a form of an MMC, an eMMC, an RS-MMC and a micro-MMC, a secure digital card in a form of an SD, a mini-SD and a micro-SD, a universal serial bus (USB) storage device, a universal flash storage (UFS) device, a personal computer memory card international association (PCMCIA) card type storage device, a peripheral component interconnection (PCI) card type storage device, a PCI express (PCI-E) card type storage device, a compact flash (CF) card, a smart media card, and a memory stick.

The storage device 50 may be manufactured as any one of various types of packages. For example, the storage device 50 may be manufactured as any one of various types of package types, such as a package on package (POP), a system in package (SIP), a system on chip (SOC), a multi-chip package (MCP), a chip on board (COB), a wafer-level fabricated package (WFP), and a wafer-level stack package (WSP).

The memory device 100 may store data. The memory device 100 operates under control of the memory controller 200. The memory device 100 may include a memory cell array including a plurality of memory cells that store data.

Each of the memory cells may be configured as a single level cell (SLC) storing one data bit, a multi-level cell (MLC) storing two data bits, a triple level cell (TLC) storing three data bits, or a quad level cell (QLC) storing four data bits.

The memory cell array may include a plurality of memory blocks. Each memory block may include a plurality of memory cells. One memory block may include a plurality of pages. In an embodiment, the page may be a unit for storing data in the memory device 100 or reading data stored in the memory device 100.

The memory block may be a unit for erasing data. In an embodiment, the memory device 100 may be a double data rate synchronous dynamic random access memory (DDR SDRAM), a low power double data rate4 (LPDDR4) SDRAM, a graphics double data rate (GDDR) SDRAM, a low power DDR (LPDDR), a Rambus dynamic random access memory (RDRAM), a NAND flash memory, a vertical NAND flash memory, a NOR flash memory device, a resistive random access memory (RRAM), a phase-change memory (PRAM), a magnetoresistive random access memory (MRAM), a ferroelectric random access memory (FRAM), a spin transfer torque random access memory (STT-RAM), or the like. In the present specification, for convenience of description, it is assumed that the memory device 100 is a NAND flash memory.

The memory device 100 is configured to receive a command and an address from the memory controller 200 and access an area selected by the address of the memory cell array. That is, the memory device 100 may perform an operation instructed by the command on the area selected by the address. For example, the memory device 100 may perform a write operation (program operation), a read operation, and an erase operation. During the program operation, the memory device 100 may program data to the area selected by the address. During the read operation, the memory device 100 may read data from the area selected by the address. During the erase operation, the memory device 100 may erase data stored in the area selected by the address.

The memory controller 200 controls overall operations of the storage device 50.

When power is applied to the storage device 50, the memory controller 200 may execute firmware FW. When the memory device 100 is a flash memory device, the memory controller 200 may operate firmware such as a flash translation layer (FTL) for controlling communication between the host and the memory device 100.

In an embodiment, the memory controller 200 may receive data and a logical block address (LBA) from the host and convert the logical block address (LBA) into a physical block address (PBA) indicating an address of memory cells in which data included in the memory device 100 is to be stored.

The memory controller 200 may control the memory device 100 to perform the program operation, the read operation, or the erase operation in response to a request from the host. During the program operation, the memory controller 200 may provide a write command, a physical block address, and data to the memory device 100. During the read operation, the memory controller 200 may provide a read command and the physical block address to the memory device 100. During the erase operation, the memory controller 200 may provide an erase command and the physical block address to the memory device 100.

In an embodiment, the memory controller 200 may generate and transmit the command, the address, and the data to the memory device 100 regardless of the request from the host. For example, the memory controller 200 may provide a command, an address, and data to the memory device 100 so as to perform background operations such as a program operation for wear leveling and a program operation for garbage collection.

In an embodiment, the memory controller 200 may control at least two memory devices 100. In this case, the memory controller 200 may control the memory devices 100 according to an interleaving method so as to improve operation performance. The interleaving method may be an operation method for overlapping operation periods of at least two memory devices 100.

In an embodiment, the memory controller 200 may include a search operation manager 210 and a block manager 220.

The search operation manager 210 may count the number of times an optimum read voltage search operation is performed on a plurality of memory blocks of the memory device 100. The optimum read voltage search operation may be an operation of determining an optimum read voltage for reading selected memory cells using a plurality of read voltages determined based on a reference read voltage when a read operation using the reference read voltage for selected memory cells of the memory block is failed.

In an embodiment, the search operation manager 210 may store the number of times the optimum read voltage search operation is performed on each of the plurality of memory blocks. In another embodiment, the search operation manager 210 may store an index of a block on which the optimum read voltage search operation is performed according to a sequence in which the optimum read voltage search operation is performed.

The search operation manager 210 may determine a memory block, in which the number of times the optimum read voltage search operation is performed exceeds a reference number of times, as a target block, based on a result of the counting. In an embodiment, the search operation manager 210 may detect whether the target block is generated whenever the optimum read voltage search operation is performed. In another embodiment, the search operation manager 210 may detect whether the target block is generated for each constant period. The constant period may include a preset time or a preset number of times the optimum read voltage search operation is performed. The word “preset” as used herein with respect to a parameter, such as a preset time or preset number of times, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

The block manager 220 may control the memory device 100 to back up data stored in the target block. The block manager 220 may control the memory device 100 to copy the data stored in the target block to another block. When the data backup is completed, the block manager 220 may set the target block as the bad block.

The bad block may be a block that might not store data among the memory blocks. The bad block may be divided into a manufacture bad block (MBB) generated during manufacturing of the memory device 100 and a growing bad block (GBB) generated in a process of using the memory block according to a time point of generation. In an embodiment, when reading memory blocks in which data is stored, a memory block in which an uncorrectable error occurs may be the growing bad block.

The host 300 may communicate with the storage device 50 using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI), a PCI express (PCIe), a nonvolatile memory express (NVMe), a universal flash storage (UFS), a secure digital (SD), a multimedia card (MMC), an embedded MMC (eMMC), a dual in-line memory module (DIMM), a registered DIMM (RDIMM), and a load reduced DIMM (LRDIMM).

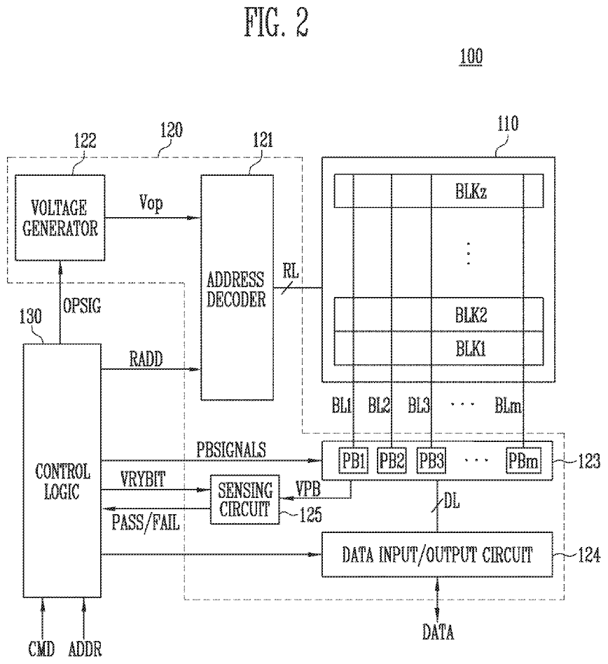

FIG. 2 is a diagram for describing a structure of the memory device of FIG. 1.

Referring to FIG. 2, the memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 includes a plurality of memory blocks BLK1 to BLKz. The plurality of memory blocks BLK1 to BLKz are connected to an address decoder 121 through row lines RL. The plurality of memory blocks BLK1 to BLKz are connected to a read and write circuit 123 through bit lines BL1 to BLm. Each of the plurality of memory blocks BLK1 to BLKz includes a plurality of memory cells. As an embodiment, the plurality of memory cells are non-volatile memory cells. Memory cells connected to the same word line among the plurality of memory cells are defined as one physical page. That is, the memory cell array 110 is configured of a plurality of physical pages. According to an embodiment of the present disclosure, each of the plurality of memory blocks BLK1 to BLKz included in the memory cell array 110 may include a plurality of dummy cells. At least one of the dummy cells may be connected in series between a drain select transistor and the memory cells and between a source select transistor and the memory cells.

Each of the memory cells of the memory device 100 may be configured as a single level cell (SLC) that stores one data bit, a multi-level cell (MLC) that stores two data bits, a triple level cell (TLC) that stores three data bits, or a quad level cell (QLC) that stores four data bits

The peripheral circuit 120 may include an address decoder 121, a voltage generator 122, the read and write circuit 123, a data input/output circuit 124, and a sensing circuit 125.

The peripheral circuit 120 drives the memory cell array 110. For example, the peripheral circuit 120 may drive the memory cell array 110 to perform a program operation, a read operation, and an erase operation.

The address decoder 121 is connected to the memory cell array 110 through the row lines RL. The row lines RL may include drain select lines, word lines, source select lines, and a common source line. According to an embodiment of the present disclosure, the word lines may include normal word lines and dummy word lines. According to an embodiment of the present disclosure, the row lines RL may further include a pipe select line.

The address decoder 121 is configured to operate in response to control of the control logic 130. The address decoder 121 receives an address ADDR from the control logic 130.

The address decoder 121 is configured to decode a block address of the received address ADDR. The address decoder 121 selects at least one memory block among the memory blocks BLK1 to BLKz according to the decoded block address. The address decoder 121 is configured to decode a row address RADD of the received address ADDR. The address decoder 121 may select at least one word line of a selected memory block by applying voltages supplied from the voltage generator 122 to at least one word line WL according to the decoded row address RADD.

During the program operation, the address decoder 121 may apply a program voltage to a selected word line and apply a pass voltage having a level less than that of the program voltage to unselected word lines. During a program verify operation, the address decoder 121 may apply a verify voltage to the selected word line and apply a verify pass voltage having a level greater than that of the verify voltage to the unselected word lines.

During the read operation, the address decoder 121 may apply a read voltage to the selected word line and apply a read pass voltage having a level greater than that of the read voltage to the unselected word lines.

According to an embodiment of the present disclosure, the erase operation of the memory device 100 is performed in memory block units. The address ADDR input to the memory device 100 during the erase operation includes a block address. The address decoder 121 may decode the block address and select one memory block according to the decoded block address. During the erase operation, the address decoder 121 may apply a ground voltage to the word lines input to the selected memory block.

According to an embodiment of the present disclosure, the address decoder 121 may be configured to decode a column address of the transferred address ADDR. The decoded column address may be transferred to the read and write circuit 123. As an example, the address decoder 121 may include a component such as a row decoder, a column decoder, and an address buffer.

The voltage generator 122 is configured to generate a plurality of operation voltages Vop by using an external power voltage supplied to the memory device 100. The voltage generator 122 operates in response to the control of the control logic 130.

As an example, the voltage generator 122 may generate an internal power voltage by regulating the external power voltage. The internal power voltage generated by the voltage generator 122 is used as an operation voltage of the memory device 100.

As an embodiment, the voltage generator 122 may generate the plurality of operation voltages Vop using the external power voltage or the internal power voltage. The voltage generator 122 may be configured to generate various voltages required by the memory device 100. For example, the voltage generator 122 may generate a plurality of erase voltages, a plurality of program voltages, a plurality of pass voltages, a plurality of selection read voltages, and a plurality of non-selection read voltages.

In order to generate the plurality of operation voltages Vop having various voltage levels, the voltage generator 122 may include a plurality of pumping capacitors that receive the internal voltage and selectively activate the plurality of pumping capacitors in response to the control logic 130 to generate the plurality of operation voltages Vop.

The plurality of generated operation voltages Vop may be supplied to the memory cell array 110 by the address decoder 121.

The read and write circuit 123 includes first to m-th page buffers PB1 to PBm. The first to m-th page buffers PB1 to PBm are connected to the memory cell array 110 through first to m-th bit lines BL1 to BLm, respectively. The first to m-th page buffers PB1 to PBm operate in response to the control of the control logic 130.

The first to m-th page buffers PB1 to PBm communicate data DATA with the data input/output circuit 124. At a time of program, the first to m-th page buffers PB1 to PBm receive the data DATA to be stored through the data input/output circuit 124 and data lines DL.

During the program operation, when a program voltage is applied to the selected word line, the first to m-th page buffers PB1 to PBm may transfer the data DATA to be stored, that is, the data DATA received through the data input/output circuit 124 to the selected memory cells through the bit lines BL1 to BLm. The memory cells of the selected page are programmed according to the transferred data DATA. A memory cell connected to a bit line to which a program permission voltage (for example, a ground voltage) is applied may have an increased threshold voltage. A threshold voltage of a memory cell connected to a bit line to which a program inhibition voltage (for example, a power voltage) is applied may be maintained. During the program verify operation, the first to m-th page buffers PB1 to PBm read the data DATA stored in the memory cells from the selected memory cells through the bit lines BL1 to BLm.

During the read operation, the read and write circuit 123 may read the data DATA from the memory cells of the selected page through the bit lines BL and store the read data DATA in the first to m-th page buffers PB1 to PBm.

During the erase operation, the read and write circuit 123 may float the bit lines BL. As an embodiment, the read and write circuit 123 may include a column selection circuit.

The data input/output circuit 124 is connected to the first to m-th page buffers PB1 to PBm through the data lines DL. The data input/output circuit 124 operates in response to the control of the control logic 130.

The data input/output circuit 124 may include a plurality of input/output buffers (not shown) that receive input data DATA. During the program operation, the data input/output circuit 124 receives the data DATA to be stored from an external controller (not shown). During the read operation, the data input/output circuit 124 outputs the data DATA transferred from the first to m-th page buffers PB1 to PBm included in the read and write circuit 123 to the external controller.

During the read operation or the verify operation, the sensing circuit 125 may generate a reference current in response to a signal of a permission bit VRYBIT generated by the control logic 130 and may compare a sensing voltage VPB received from the read and write circuit 123 with a reference voltage generated by the reference current to output a pass signal or a fail signal to the control logic 130.

The control logic 130 may be connected to the address decoder 121, the voltage generator 122, the read and write circuit 123, the data input/output circuit 124, and the sensing circuit 125. The control logic 130 may be configured to control all operations of the memory device 100. The control logic 130 may operate in response to a command CMD transferred from an external device.

The control logic 130 may generate various signals in response to the command CMD and the address ADDR to control the peripheral circuit 120. For example, the control logic 130 may generate an operation signal OPSIG, the row address RADD, a read and write circuit control signal PBSIGNALS, and the permission bit VRYBIT in response to the command CMD and the address ADDR. The control logic 130 may output the operation signal OPSIG to the voltage generator 122, output the row address RADD to the address decoder 121, output the read and write control signal to the read and write circuit 123, and output the permission bit VRYBIT to the sensing circuit 125. In addition, the control logic 130 may determine whether the verify operation is passed or failed in response to the pass or fail signal PASS/FAIL output by the sensing circuit 125.

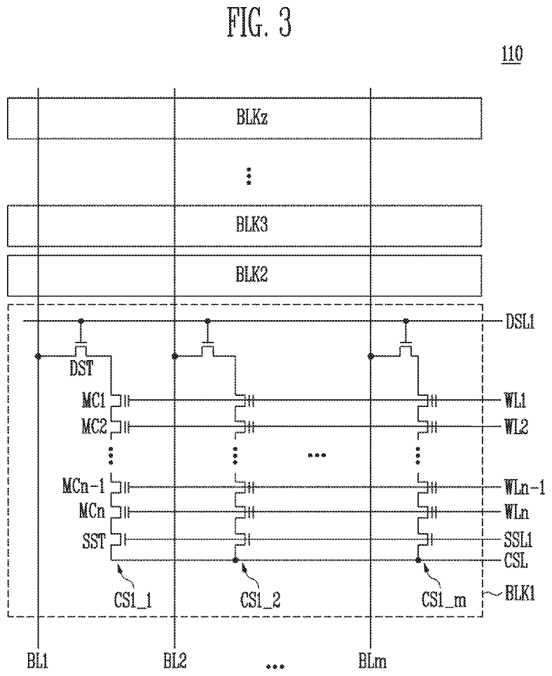

FIG. 3 is a diagram for describing the memory cell array of FIG. 2.

Referring to FIG. 3, the first to z-th memory blocks BLK1 to BLKz are commonly connected to the first to m-th bit lines BL1 to BLm. In FIG. 3, for convenience of description, elements included in the first memory block BLK1 of the plurality of memory blocks BLK1 to BLKz are shown, and elements included in each of the remaining memory blocks BLK2 to BLKz are omitted. It will be understood that each of the remaining memory blocks BLK2 to BLKz is configured similarly to the first memory block BLK1.

The memory block BLK1 may include a plurality of cell strings CS1_1 to CS1_m (m is a positive integer). The first to m-th cell strings CS1_1 to CS1_m are connected to the first to m-th bit lines BL1 to BLm, respectively. Each of the first to m-th cell strings CS1_1 to CS1_m includes a drain select transistor DST, a plurality of memory cells MC1 to MCn connected in series (n is a positive integer), and a source select transistor SST.

Gate terminals of the drain select transistors DST included in each of the first to m-th cell strings CS1_1 to CS1_m are connected to a drain select line DSL1. Gate terminals of the first to n-th memory cells MC1 to MCn included in each of the first to m-th cell strings CS1_1 to CS1_m are connected to the first to n-th word lines WL1 to WLn, respectively. Gate terminals of the source select transistors SST included in each of the first to m-th cell strings CS1_1 to CS1_m are connected to a source select line SSL1.

For convenience of description, a structure of the cell string will be described with reference to the first cell string CS1_1 of the plurality of cell strings CS1_1 to CS1_m. However, it will be understood that each of the remaining cell strings CS1_2 to CS1_m is configured similarly to the first cell string CS1_1.

A drain terminal of the drain select transistor DST included in the first cell string CS1_1 is connected to the first bit line BL1. A source terminal of the drain select transistor DST included in the first cell string CS1_1 is connected to a drain terminal of the first memory cell MC1 included in the first cell string CS1_1. The first to n-th memory cells MC1 to MCn are connected in series with each other. A drain terminal of the source select transistor SST included in the first cell string CS1_1 is connected to a source terminal of the n-th memory cell MCn included in the first cell string CS1_1. A source terminal of the source select transistor SST included in the first cell string CS1_1 is connected to a common source line CSL. As an embodiment, the common source line CSL may be commonly connected to the first to z-th memory blocks BLK1 to BLKz.

The drain select line DSL1, the first to n-th word lines WL1 to WLn, and the source select line SSL1 are included in row lines RL of FIG. 2. The drain select line DSL1, the first to n-th word lines WL1 to WLn, and the source select line SSL1 are controlled by the address decoder 121. The common source line CSL is controlled by the control logic 130. The first to m-th bit lines BL1 to BLm are controlled by the read and write circuit 123.

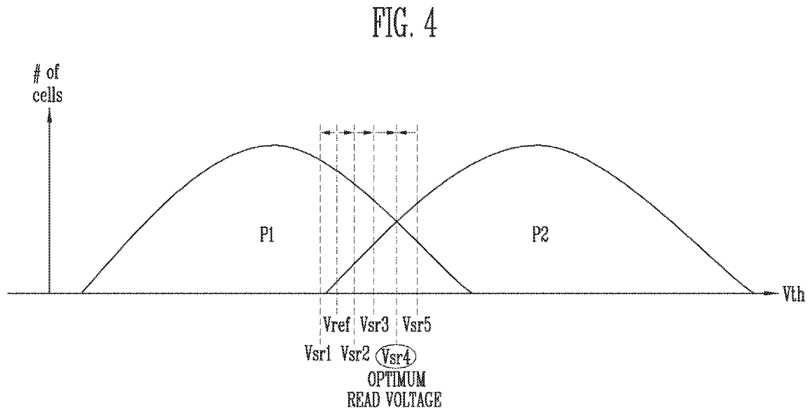

FIG. 4 is a diagram for describing the optimum read voltage search operation according to an embodiment.

Referring to FIG. 4, it will be described under an assumption that memory cells have any one state of a first state and a second state. A threshold voltage distribution corresponding to the first state may be P1. The threshold voltage distribution corresponding to the second state may be P2.

When the read operation using a reference read voltage Vref is failed, an optimum read voltage may be determined using a plurality of read voltages Vsr1 to Vsr5 determined based on the reference read voltage Vref. The plurality of read voltages Vsr1 to Vsr5 may be a read voltage obtained by adding an offset based on the reference read voltage Vref. The offset may have a positive value or a negative value.

In an embodiment, the reference read voltage Vref may be a voltage used for the failed read operation. In another embodiment, the reference read voltage Vref may be an initial read voltage set to divide the threshold voltage distribution of the memory cells in a manufacturing process step.

The optimum read voltage may be determined based on a cell count value obtained by counting the number of memory cells belonging to a section divided by a plurality of read voltages. For example, a soft read may progress in a direction in which the cell count value decreases, and a read voltage when the cell count value is minimum may be determined as the optimum read voltage.

For example, when the read operation by the reference read voltage Vref is failed, the soft read operation may be performed by a read voltage Vsr1 of a level lower than the reference read voltage. Thereafter, the soft read operation may be performed by a read voltage Vsr2 of a level higher than the reference read voltage.

Since the cell count value of a section determined by the read voltages Vref and Vsr2 is smaller than the cell count value of a section determined by the read voltages Vsr1 and Vref, the optimum read voltage may be predicted to be positioned to a right side of the reference read voltage Vref. In other words, the optimum read voltage may be predicted to have a level higher than the reference read voltage Vref.

When a direction according to the position of the optimum read voltage is determined, the soft read operation may be performed by using the read voltages Vsr2 to Vsr5 obtained by adding the offset in the determined direction.

In the same manner as described above, cell count values of each section may be calculated. An arrow may be a direction in which the soft read progresses. In FIG. 4, the cell count value of the section determined by read voltages Vsr3 and Vsr4 may be minimum, and a read voltage Vsr4 corresponding thereto may be determined as the optimum read voltage.

The optimum read voltage search operation may be an operation of determining the optimum read voltage for successfully reading the memory cells when the memory cells might not be read by using the reference read voltage because disturbance or retention of the memory cells is intensified. The optimum read voltage may be determined through the soft read operation using a plurality of read voltages determined based on the reference read voltage.

In an embodiment, the higher the number of times the optimum read voltage search operation is performed in the same memory block, the greater a physical defect level of the memory block. Therefore, in an embodiment, the storage device may detect a target block having a high probability of defect according to the number of times the optimum read voltage search operation is performed, back up data of the target block before the data of the target block is lost, and process the target block as the bad block. According to an embodiment, the memory block may be separately managed and data loss may be prevented, by predicting damage of the memory block according to the number of times the optimum read voltage search operation is performed. Thus, reliability of the storage device may be improved.

FIG. 5 is a diagram for describing a configuration and an operation of the memory controller of FIG.

Referring to FIG. 5, the memory controller 200 may include a search operation manager 210 and a block manager 220. The search operation manager 210 may include a search operation counter 211 and a target block detector 212.

In an embodiment, the search operation counter 211 may include a search table storage 211a. In another embodiment, the search table storage 211a may be positioned outside the search operation counter 211.

The search operation counter 211 may count the number of times the optimum read voltage search operation is performed on the plurality of memory blocks based on an optimum read voltage search operation information ORS_OP, The optimum read voltage search operation information ORS_OP may be information indicating that the optimum read operation is performed. The optimum read voltage search operation information ORS_OP may include an index of a block on which the optimum read voltage search operation is performed.

The optimum read voltage search operation may be an operation of determining the optimum read voltage for reading the selected memory cells using the plurality of read voltages determined based on the reference read voltage when the read operation using the reference read voltage for the selected memory cells of the memory block has failed.

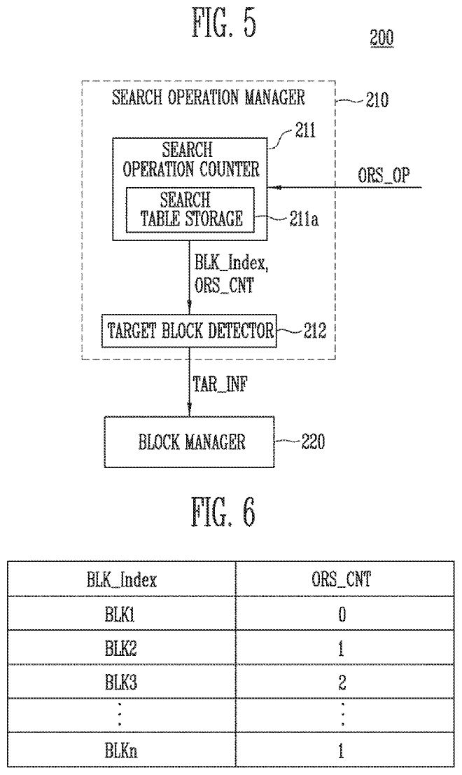

The search table storage 211a may write the number of times the optimum read voltage search operation is performed in a search table. In an embodiment, the search table may store the number of times the optimum read voltage search operation is performed on each of the plurality of memory blocks, as will be described later with reference to FIG. 6. In another embodiment, the search table may store an index of a block on which the optimum read voltage search operation is performed according to a sequence in which the optimum read voltage search operation is performed, as will be described later with reference to FIG. 7.

In various embodiments, since the optimum read voltage search operation is not frequent in a start-of-life (SOL) step of the memory device, the search table storage 211a may manage the search table described with reference to FIG. 7 occupying less memory capacity. Since the optimum read voltage search operation is frequent in an end-of-life (EOL) step, the search table storage 211a may immediately manage the search table described with reference to FIG. 6, which may detect the target block.

The search operation counter 211 may provide a block index BLK_Index of the memory block, which is stored in the search table, and a count value ORS_CNT at which the optimum read voltage search operation is performed on a corresponding memory block, to the target block detector 212.

The target block detector 212 may determine the memory block, in which the number of times the optimum read voltage search operation is performed exceeds the reference number of times, as the target block, based on the search table. For example, the target block detector 212 may determine whether a memory block corresponding to the block index BLK_Index is the target block based on a comparison result of the count value ORS_CNT and the reference number of times. The target block detector 212 may determine a memory block, in which the count value ORS_CNT is greater than the reference number of times, as the target block.

In an embodiment, the target block detector 212 may detect whether the target block is generated whenever the optimum read voltage search operation is performed. In another embodiment, the target block detector 212 may detect whether the target block is generated for each constant period. The constant period may include a preset time or a preset number of times the optimum read voltage search operation is performed. In an embodiment, the constant period may include a preset amount of time that may vary, for example but not limited to, after each optimum read voltage search operation is performed.

The target block detector 212 may provide determined target block related information TAR_INF to the block manager 220.

The block manager 220 may control the memory device 100 to back up the data stored in the target block based on the target block related information TAR_INF. The block manager 220 may control the memory device to copy the data stored in the target block to another block. When the data backup is completed, the block manager 220 may set the target block as the bad block.

The bad block may be a block that might not store data among the memory blocks. The bad block may be divided into a manufacture bad block (MBB) generated during manufacturing of the memory device 100 and a growing bad block (GBB) generated in a process of using the memory block according to a time point of generation. In an embodiment, when reading memory blocks in which data is stored, a memory block in which an uncorrectable error occurs may be the growing bad block.

FIG. 6 is a diagram for describing the search table storage of FIG. 5 according to an embodiment.

Referring to FIG. 6, the memory device may include a plurality of memory blocks BLK1 to BLKn (n is a natural number equal to or greater than 1). The search table storage may write the number of times ORS CNT the optimum read voltage search operation corresponding to each of the plurality of memory blocks BLK1 to BLKn is performed in the search table.

For example, the number of times the optimum read voltage search operation of the memory block BLK1 is performed may be 0 times. The number of times the optimum read voltage search operation of the memory block BLK2 is performed may be once. The number of times the optimum read voltage search operation of the memory block BLK3 is performed may be twice. The number of times the optimum read voltage search operation of the memory block BLKn is performed may be once.

Whenever the optimum read voltage search operation is performed, the count value ORS_CNT of the block on which the optimum read voltage search operation is performed may be updated in the search table.

In an embodiment, the memory block in which the count value ORS_CNT exceeds the reference number of times may be determined as the target block. For example, assuming that the reference number of times for determining the target block is 1, the memory block BLK3 in which the count value ORS_CNT exceeds the reference number of times may be determined as the target block.

In a case of the search table described with reference to FIG. 6, there is an advantage in that it is possible to immediately determine whether a target block corresponds whenever the search table is updated. Therefore, the search table may be usefully utilized in the end-of-life (EOL) step of the memory device in which the optimum read voltage search operation is frequently performed.

FIG. 7 is a diagram for describing the search table storage of FIG. 5 according to another embodiment.

Referring to FIG. 7, the search table storage may write the block index BLK_Index of the block on which the optimum read voltage search operation is performed in the search table according to a sequence ORS Seq in which the optimum read voltage search operation is performed. The number of times the optimum read voltage search operation is performed on the block on which the optimum read voltage search operation is performed may be calculated, based on the block index BLK_Index stored in the search table.

For example, the memory block BLK2 may be a block on which a first optimum read voltage search operation is performed. The memory block BLK3 may be a block on which a second optimum read voltage search operation is performed. The memory block BLK1 may be a block on which a third optimum read voltage search operation is performed. The memory block BLK3 may be a block on which a fourth optimum read voltage search operation is performed.

Therefore, the number of times the optimum read voltage search operation of the memory block BLK1 is performed may be once. The number of times the optimum read voltage search operation of the memory block BLK2 is performed may be once. The number of times the optimum read voltage search operation of the memory block BLK3 is performed may be twice.

In an embodiment, the memory block in which the number of times the optimum read voltage search operation is performed exceeds the reference number of times may be determined as the target block. For example, assuming that the reference number of times for determining the target block is 1, the memory block BLK3 in which the number of times the optimum read voltage search operation is performed exceeds the reference number may be determined as the target block.

In a case of the search table described with reference to FIG. 7, since the block index is stored only for the block on which the search table is performed, there is an advantage in that a small memory capacity is occupied. Therefore, the search table may be usefully utilized in the start-of-life (SOL) step of the memory device on which the optimum read voltage search operation is not frequently performed.

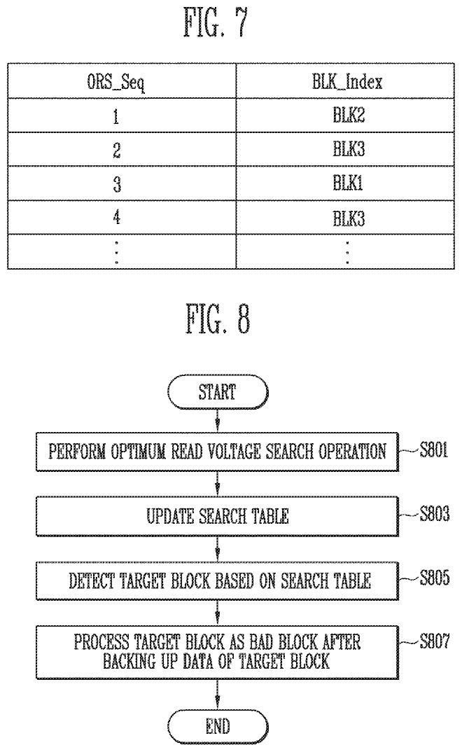

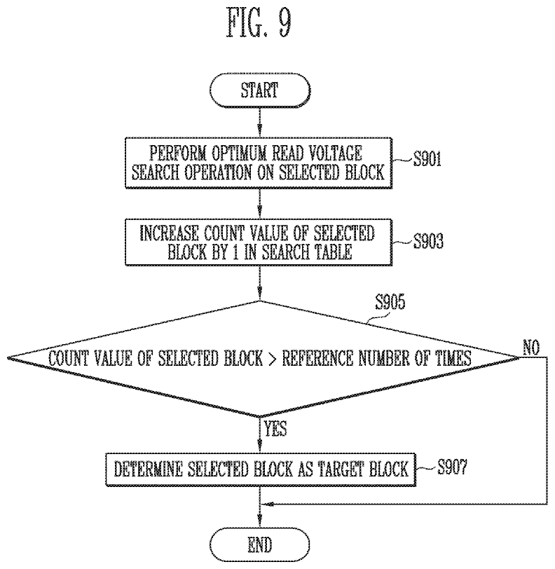

FIG. 8 is a diagram for describing an operation of the storage device of FIG. 1 according to an embodiment.

Referring to FIG. 8, in step S801, the storage device may perform the optimum read voltage search operation.

In step S803, the storage device may update the search table. The search table may include the search table described with reference to FIG. 6. The search table may include the search table described with reference to FIG. 7.

In step S805, the storage device may detect the target block based on the search table. For example, the storage device may determine the memory block, in which the number of times the optimum read voltage search operation is performed exceeds the reference number of times, as the target block.

In step S807, the storage device may set the target block as the bad block after backing up the data of the target block.

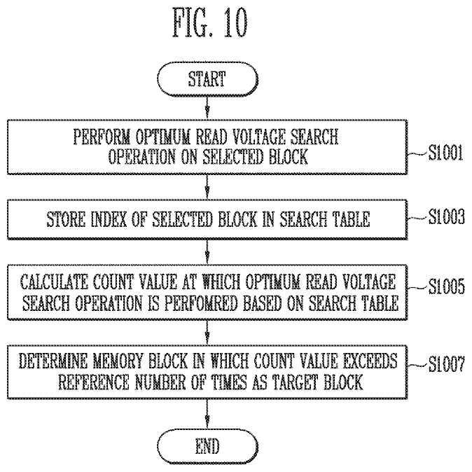

FIG. 9 is a diagram for describing determination of the target block according to an embodiment.

Referring to FIG. 9, in step S901, the optimum read voltage search operation for the selected block may be performed.

In step S903, the count value of the selected block may increase by one in the search table. The count value may indicate the number of times the optimum read voltage search operation is performed on the selected block. The search table may be the search table described with reference to FIG. 6.

In step S905, it may be determined whether the count value of the selected block is greater than the reference number of times. The reference number of times may indicate the reference number of times for determining the target block. When the count value is greater than the reference number of times, the operation proceeds to step S907. When the count value is less than or equal to the reference number of times, the operation is ended.

In step S907, the selected block may be determined as the target block.

FIG. 10 is a diagram for describing the determination of the target block according to other embodiments.

Referring to FIG. 10, in step S1001, the optimum read voltage search operation for the selected block may be performed.

In step S1003, the index of the selected block may be stored in the search table. The search table may be the search table described with reference to FIG. 7.

In step S1005, the count value at which the optimum read voltage search operation is performed may be calculated based on the search table.

In step S1007, the memory block in which the count value exceeds the reference number of times may be determined as the target block.

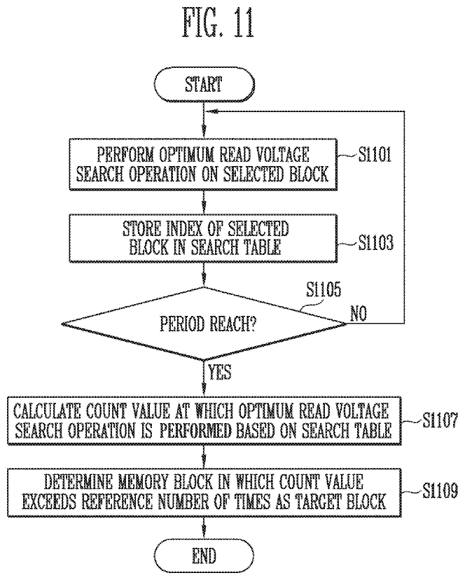

FIG. 11 is a diagram for describing the determination of the target block according to other embodiments.

Referring to FIG. 11, in step S1101, the optimum read voltage search operation for the selected block may be performed.

In step S1103, the index of the block on which the optimum read voltage search operation is performed may be stored in the search table. The search table may be the search table described with reference to FIG. 7.

In step S1105, it may be determined whether an elapsed period reaches a period. As a result of the determination, when the elapsed period reaches the period, the operation proceeds to step S1107, otherwise, the process proceeds to step S1101. When the elapsed period reaches the period, the elapsed period may be reset. The period may be a preset time. Alternatively, the period may be a preset number of times the optimum read voltage search operation is performed.

In step S1107, the count value at which the optimum read voltage search operation is performed may be calculated based on the search table.

In step S1109, the memory block in which the count value exceeds the reference number of times may be determined as the target block.

According to the embodiments described with reference to FIG. 11, apart from the embodiments described with reference to FIG. 10, the target block determination operation may be performed for each constant period rather than performing the target block determination operation whenever optimum read voltage update operation is performed. Therefore, cost due to performance of frequent target block determination operations may be reduced.

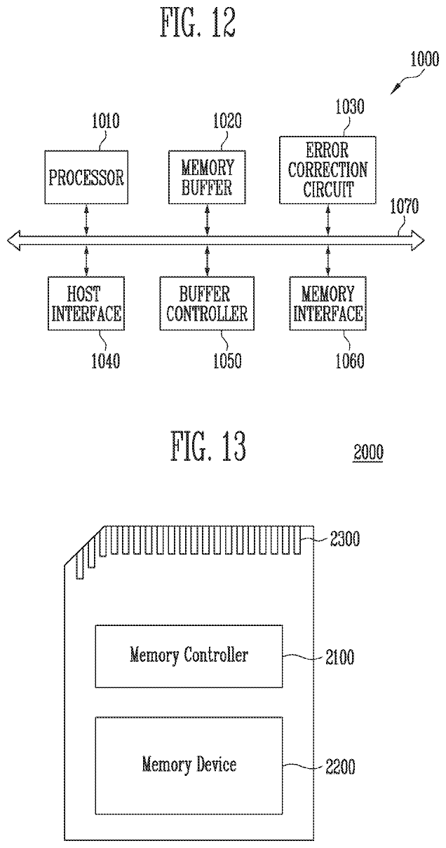

FIG. 12 is a diagram for describing other embodiments of the memory controller of FIG. 1.

Referring to FIG. 12, the memory controller 1000 is connected to a host Host and the memory device. The memory controller 1000 is configured to access the memory device in response to the request from the host Host. For example, the memory controller 1000 is configured to control the write, read, erase, and background operations of the memory device. The memory controller 1000 is configured to provide an interface between the memory device and the host Host. The memory controller 1000 is configured to drive firmware for controlling the memory device.

The memory controller 1000 may include a processor 1010, a memory buffer 1020, an error correction circuit (ECC) 1030, a host interface 1040, a buffer control circuit 1050, a memory interface 1060, and a bus 1070.

The bus 1070 may be configured to provide a channel between components of the memory controller 1000.

The processor 1010 may control overall operations of the memory controller 1000 and may perform a logical operation. The processor 1010 may communicate with an external host through the host interface 1040 and communicate with the memory device through the memory interface 1060. In addition, the processor 1010 may communicate with the memory buffer 1020 through the buffer controller 1050. The processor 1010 may control an operation of the storage device using the memory buffer 1020 as an operation memory, a cache memory, or a buffer memory.

The processor 1010 may perform a function of a flash translation layer (FTL). The processor 1010 may convert a logical block address (LBA) provided by the host into a physical block address (PBA) through the flash translation layer (FTL). The flash translation layer (FTL) may receive the logical block address (LBA) using a mapping table and convert the logical block address (LBA) into the physical block address (PBA). An address mapping method of the flash translation layer may include various methods according to a mapping unit. A representative address mapping method includes a page mapping method, a block mapping method, and a hybrid mapping method.

The processor 1010 is configured to randomize data received from the host Host. For example, the processor 1010 may randomize the data received from the host Host using a randomizing seed. The randomized data is provided to the memory device as data to be stored and is programmed to the memory cell array.

The processor 1010 is configured to de-randomize data received from the memory device during the read operation. For example, the processor 1010 may de-randomize the data received from the memory device using a de-randomizing seed. The de-randomized data may be output to the host Host.

As an embodiment, the processor 1010 may perform the randomization and the de-randomization by driving software or firmware.

The memory buffer 1020 may be used as an operation memory, a cache memory, or a buffer memory of the processor 1010. The memory buffer 1020 may store codes and commands executed by the processor 1010. The memory buffer 1020 may store data processed by the processor 1010. The memory buffer 1020 may include a static RAM (SRAM) or a dynamic RAM (DRAM).

The error correction circuit 1030 may perform error correction. The error correction circuit 1030 may perform error correction encoding (ECC encoding) based on data to be stored in the memory device through memory interface 1060. The error correction encoded data may be transferred to the memory device through the memory interface 1060. The error correction circuit 1030 may perform error correction decoding (ECC decoding) on the data received from the memory device through the memory interface 1060. For example, the error correction circuit 1030 may be included in the memory interface 1060 as a component of the memory interface 1060.

The host interface 1040 is configured to communicate with an external host under control of the processor 1010. The host interface 1040 may be configured to perform communication using at least one of various communication methods such as a universal serial bus (USB), a serial AT attachment (SATA), a serial attached SCSI (SAS), a high speed interchip (HSIC), a small computer system interface (SCSI), a peripheral component interconnection (PCI express), a nonvolatile memory express (NVMe), a universal flash storage (UFS), a secure digital (SD), a multimedia card (MMC), an embedded MMC (eMMC), a dual in-line memory module (DIMM), a registered DIMM (RDIMM), and a load reduced DIMM (LRDIMM).

The buffer controller 1050 is configured to control the memory buffer 1020 under the control of the processor 1010.

The memory interface 1060 is configured to communicate with the memory device under the control of the processor 1010. The memory interface 1060 may communicate a command, an address, and data with the memory device through a channel.

For example, the memory controller 1000 might not include the memory buffer 1020 and the buffer controller 1050.

For example, the processor 1010 may control the operation of the memory controller 1000 using codes. The processor 1010 may load the codes from a non-volatile memory device (for example, a read only memory) provided inside the memory controller 1000. As another example, the processor 1010 may load the codes from the memory device through the memory interface 1060.

For example, the bus 1070 of the memory controller 1000 may be divided into a control bus and a data bus. The data bus may be configured to transmit data within the memory controller 1000 and the control bus may be configured to transmit control information such as a command and an address within the memory controller 1000. The data bus and the control bus may be separated from each other and might not interfere with each other or affect each other. The data bus may be connected to the host interface 1040, the buffer controller 1050, the error correction circuit 1030, and the memory interface 1060. The control bus may be connected to the host interface 1040, the processor 1010, the buffer controller 1050, the memory buffer 1202, and the memory interface 1060.

In an embodiment, the search operation manager 210 and the block manager 220 described with reference to FIG. may be included in the processor 1010.

FIG. 13 is a block diagram illustrating a memory card system to which the storage device according to an embodiment of the present disclosure is applied.

Referring to FIG. 13, the memory card system 2000 includes a memory controller 2100, a memory device 2200, and a connector 2300.

The memory controller 2100 is connected to the memory device 2200. The memory controller 2100 is configured to access the memory device 2200. For example, the memory controller 2100 may be configured to control read, write, erase, and background operations of the memory device 2200. The memory controller 2100 is configured to provide an interface between the memory device 2200 and a host. The memory controller 2100 is configured to drive firmware for controlling the memory device 2200. The memory controller 2100 may be implemented identically or similarly to the memory controller 200 described with reference to FIG. 1.

For example, the memory controller 2100 may include components such as a random access memory (RAM), a processor, a host interface, a memory interface, and an error correction circuit.

The memory controller 2100 may communicate with an external device through the connector 2300. The memory controller 2100 may communicate with an external device (for example, the host) according to a specific communication standard. For example, the memory controller 2100 is configured to communicate with an external device through at least one of various communication standards such as a universal serial bus (USB), a multimedia card (MMC), an embedded MMC (MCM), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe. For example, the connector 2300 may be defined by at least one of the various communication standards described above.

For example, the memory device 2200 may be configured of various non-volatile memory elements such as an electrically erasable and programmable ROM (EEPROM), a NAND flash memory, a NOR flash memory, a phase-change RAM (PRAM), a resistive RAM (ReRAM), a ferroelectric RAM (FRAM), and a spin-torque magnetic RAM (STT-MRAM).

The memory controller 2100 and the memory device 2200 may be integrated into one semiconductor device to configure a memory card. For example, the memory controller 2100 and the memory device 2200 may be integrated into one semiconductor device to configure a memory card such as a PC card (personal computer memory card international association (PCMCIA)), a compact flash card (CF), a smart media card (SM or SMC), a memory stick, a multimedia card (MMC, RS-MMC, MMCmicro, or eMMC), an SD card (SD, miniSD, microSD, or SDHC), and a universal flash storage (UFS).

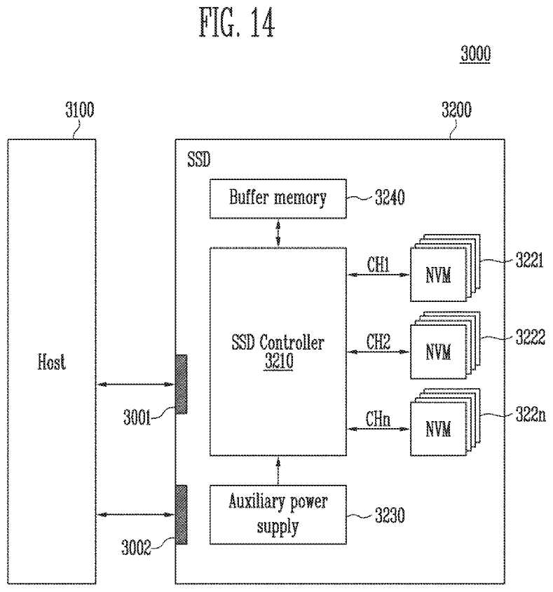

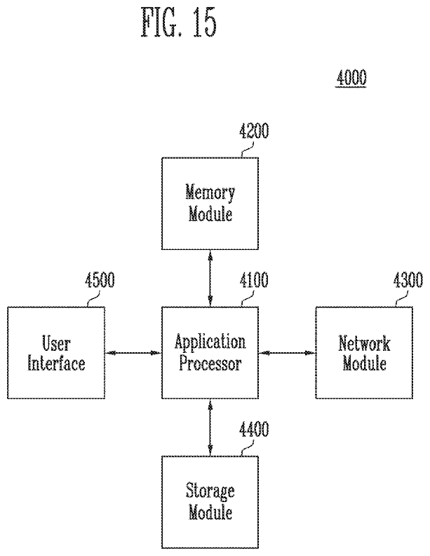

FIG. 14 is a block diagram illustrating a solid state drive (SSD) system to which the storage device according to an embodiment of the present disclosure is applied.

Referring to FIG. 14, the SSD system 3000 includes a host 3100 and an SSD 3200. The SSD 3200 exchanges a signal SIG with the host 3100 through a signal connector 3001 and receives power PWR through a power connector 3002. The SSD 3200 includes an SSD controller 3210, a plurality of flash memories 3221 to 322n, an auxiliary power device 3230, and a buffer memory 3240.

According to an embodiment of the present disclosure, the SSD controller 3210 may perform the function of the memory controller 200 described with reference to FIG.

The SSD controller 3210 may control the plurality of flash memories 3221 to 322n in response to the signal SIG received from the host 3100. For example, the signal SIG may be signals based on an interface between the host 3100 and the SSD 3200. For example, the signal SIG may be a signal defined by at least one of interfaces such as a universal serial bus (USB), a multimedia card (MMC), an embedded MMC (MCM), a peripheral component interconnection (PCI), a PCI express (PCI-E), an advanced technology attachment (ATA), a serial-ATA, a parallel-ATA, a small computer system interface (SCSI), an enhanced small disk interface (ESDI), integrated drive electronics (IDE), FireWire, a universal flash storage (UFS), Wi-Fi, Bluetooth, and an NVMe.

The auxiliary power device 3230 is connected to the host 3100 through the power connector 3002. The auxiliary power device 3230 may receive the power PWR from the host 3100 and may charge the power. The auxiliary power device 3230 may provide power of the SSD 3200 when power supply from the host 3100 is not smooth. For example, the auxiliary power device 3230 may be positioned in the SSD 3200 or may be positioned outside the SSD 3200. For example, the auxiliary power device 3230 may be positioned on a main board and may provide auxiliary power to the SSD 3200.

The buffer memory 3240 operates as a buffer memory of the SSD 3200. For example, the buffer memory 3240 may temporarily store data received from the host 3100 or data received from the plurality of flash memories 3221 to 322n, or may temporarily store metadata (for example, a mapping table) of the flash memories 3221 to 322n. The buffer memory 3240 may include a volatile memory such as a DRAM, an SDRAM, a DDR SDRAM, an LPDDR SDRAM, and a GRAM, or a non-volatile memory such as an FRAM, a ReRAM, an STT-MRAM, and a PRAM.

FIG. 15 is a block diagram illustrating a user system to which the storage device according to an embodiment of the present disclosure is applied.

Referring to FIG. 15, the user system 4000 includes an application processor 4100, a memory module 4200, a network module 4300, a storage module 4400, and a user interface 4500.

The application processor 4100 may drive components, an operating system (OS), a user program, or the like included in the user system 4000. For example, the application processor 4100 may include controllers, interfaces, graphics engines, and the like that control the components included in the user system 4000. The application processor 4100 may be provided as a system-on-chip (SoC).

The memory module 4200 may operate as a main memory, an operation memory, a buffer memory, or a cache memory of the user system 4000. The memory module 4200 may include a volatile random access memory such as a DRAM, an SDRAM, a DDR SDRAM, a DDR2 SDRAM, a DDR3 SDRAM, an LPDDR SDARM, an LPDDR2 SDRAM, and an LPDDR3 SDRAM, or a non-volatile random access memory, such as a PRAM, a ReRAM, an MRAM, and an FRAM, For example, the application processor 4100 and memory module 4200 may be packaged based on a package on package (POP) and provided as one semiconductor package.

The network module 4300 may communicate with external devices. For example, the network module 4300 may support wireless communication such as code division multiple access (CDMA), global system for mobile communications (GSM), wideband CDMA (WCDMA), CDMA-2000, time division multiple access (TDMA), long term evolution, Wimax, WLAN, UWB, Bluetooth, and Wi-Fi. For example, the network module 4300 may be included in the application processor 4100.

The storage module 4400 may store data. For example, the storage module 4400 may store data received from the application processor 4100. Alternatively, the storage module 4400 may transmit data stored in the storage module 4400 to the application processor 4100. For example, the storage module 4400 may be implemented as a non-volatile semiconductor memory element such as a phase-change RAM (PRAM), a magnetic RAM (MRAM), a resistive RAM (RRAM), a NAND flash, a NOR flash, and a three-dimensional NAND flash. For example, the storage module 4400 may be provided as a removable storage device (removable drive), such as a memory card, and an external drive of the user system 4000.

For example, the storage module 4400 may include a plurality of non-volatile memory devices, and the plurality of non-volatile memory devices may operate identically or similarly to the memory device 100 described with reference to FIG. 1. The storage module 4400 may operate identically or similarly to the storage device 50 described with reference to FIG.

The user interface 4500 may include interfaces for inputting data or an instruction to the application processor 4100 or for outputting data to an external device. For example, the user interface 4500 may include user input interfaces such as a keyboard, a keypad, a button, a touch panel, a touch screen, a touch pad, a touch ball, a camera, a microphone, a gyroscope sensor, a vibration sensor, and a piezoelectric element. The user interface 4500 may include user output interfaces such as a liquid crystal display (LCD), an organic light emitting diode (OLED) display device, an active matrix OLED (AMOLED) display device, an LED, a speaker, and a monitor.

What is claimed is:

1. A memory controller for controlling a memory device including a plurality of memory blocks, the memory controller comprising:
a search operation manager configured to count a number of times an optimum read voltage search operation is performed on the plurality of memory blocks, and to determine a target block in which the number of times the optimum read voltage search operation is performed exceeds a reference number of times; and
a block manager configured to set the target block as a bad block.

2. The memory controller of claim 1, wherein the search operation manager comprises:
a search operation counter configured to count the number of times the optimum read voltage search operation is performed; and
a target block detector configured to detect the target block based on a result of counting the number of times the optimum read voltage search operation is performed.

3. The memory controller of claim 2, wherein the search operation counter includes a search table storage configured to write the number of times the optimum read voltage search operation is performed in a search table.

4. The memory controller of claim 3, wherein the search table stores the number of times the optimum read voltage search operation is performed on each of the plurality of memory blocks.

5. The memory controller of claim 3, wherein when the optimum read voltage search operation is performed, the search table stores an index of a memory block on which the optimum read voltage search operation is performed.

6. The memory controller of claim 3, wherein the target block detector detects the target block based on the search table whenever the search table is updated.

7. The memory controller of claim 3, wherein the target block detector detects the target block based on the search table for each constant period.

8. The memory controller of claim 7, wherein the constant period indicates at least one of a set time and a set number of times the optimum read voltage search operation is performed.

9. The memory controller of claim 1, wherein the block manager controls the memory device to perform a backup operation of copying data stored in the target block to a memory block different from the target block among the plurality of memory blocks.

10. The memory controller of claim 1, wherein the optimum read voltage search operation is an operation of determining an optimum read voltage for reading memory cells using a plurality of read voltages determined based on a reference read voltage when a read operation using the reference read voltage for the memory cells of the memory block has failed.

11. A storage device comprising:
a memory device including a plurality of memory blocks; and
a memory controller configured to count a number of times an optimum read voltage search operation is performed on the plurality of memory blocks.

12. The storage device of claim 11, wherein the memory controller is configured to set a target block, in which the number of times the optimum read voltage search operation is performed exceeds a reference number of times, as a bad block.

13. The storage device of claim 12, wherein the memory controller stores the number of times the optimum read voltage search operation is performed on each of the plurality of memory blocks.

14. The storage device of claim 12, wherein when the optimum read voltage search operation is performed, the memory controller stores an index of a memory block on which the optimum read voltage search operation is performed.

15. The storage device of claim 12, wherein the memory controller detects the target block based on a result of the counting whenever at least one of the optimum read voltage search operation is performed and for each constant period, and
the constant period indicates one of a set time and a set number of times the optimum read voltage search operation is performed.

16. A method of operating a storage device including a plurality of memory blocks, the method comprising:
counting a number of times an optimum read voltage search operation is performed on the plurality of memory blocks; and
determining a target block in which the number of times the optimum read voltage search operation is performed exceeds a reference number of times among the plurality of memory blocks based on a result of the counting.

17. The method of claim 16, further comprising:
copying data stored in the target block to a memory block different from the target block among the plurality of memory blocks; and
setting the target block as a bad block.

18. The method of claim 16, wherein determining the target block comprises:
writing the number of times the optimum read voltage search operation is performed on the plurality of memory blocks in a search table; and
detecting the target block based on the search table.

19. The method of claim 18, wherein the search table stores the number of times the optimum read voltage search operation is performed on each of the plurality of memory blocks.

20. The method of claim 18, wherein when the optimum read voltage search operation is performed, the search table stores an index of a memory block on which the optimum read voltage search operation is performed.

21. The method of claim 18, wherein detecting the target block comprises detecting the target block based on the search table whenever at least one of the search table is updated and for each constant period, and
the constant period indicates one of a set time and a set number of times the optimum read voltage search operation is performed.
